(19) United States
(12) Patent Application Publication
(10) Pub. No.: US 2026/0239553 A1
(43) Pub. Date: Aug. 13, 2026

(54) Dovetail Rail Chassis for Printed Circuit Boards

(71) Applicant: NATIONAL INSTRUMENTS CORPORATION, Austin, TX (US)

(72) Inventors: Christopher White, Round Rock, TX (US); Jacob Stephen Friedrich, Austin, TX (US)

(21) Appl. No.: 19/050,430

(22) Filed: Feb. 11, 2025

(51) Int. Cl. H05K 7/14; H05K 7/20

(52) U.S. Cl. CPC H05K 7/1427; H05K 7/1401; H05K 7/2039

(57) ABSTRACT

An electronics chassis includes an enclosure configured to house a printed circuit board (PCB). The enclosure includes one or more dovetail rails that are configured to affix one or more heat spreaders to the enclosure at a customizable position while the one or more heat spreaders are in thermal contact with the PCB.

### BACKGROUND

### Technical Field

The present invention relates generally to devices to house and cool electronic circuit boards, and more particularly, to the cooling of components by heat spreaders.

### Description of the Related Art

Various types of electronic devices may be mounted in a chassis or enclosure in order to facilitate interfacing with the devices, containing the devices, managing the devices, or other reasons. Some electronic devices generate excess heat in the course of their operation, and it may be difficult to provide effective heat sinks, particularly in a small or confined space. Accordingly, improvements in the field of electronics chassis are desired.

### SUMMARY

Embodiments herein describe methods and chassis that are configured to house a printed circuit board (PCB) and/or other electronic circuity in a slot and a system for providing cooling, an example of which is a heat spreader in thermal contact with both the PCB and the ceiling of the enclosure. A PCB module may be inserted into slots in the chassis. The plugin modules, which may be referred to herein as ‘modules’ or ‘electronic devices’, may be comprised of processor chips, field programmable gate arrays (FPGAs), programmable logic devices (PLDs), application specific integrated circuits (ASICs), or other devices, in various embodiments.

In some embodiments, an electronics chassis comprises an enclosure configured to house a PCB while it is arranged along a first plane. The enclosure comprises one or more dovetail rails arranged along a first direction that is parallel to the first plane.

In some embodiments, the one or more dovetail rails are configured to affix one or more heat spreaders to the enclosure at a customizable position along the first direction while the one or more heat spreaders are in thermal contact with the PCB.

Note that the techniques described herein may be implemented in and/or used with a number of different types of devices. This Summary is intended to provide a brief overview of some of the subject matter described in this document. Accordingly, it will be appreciated that the above-described features are merely examples and should not be construed to narrow the scope or spirit of the subject matter described herein in any way. Other features, aspects, and advantages of the subject matter described herein will become apparent from the following Detailed Description, Figures, and Claims.

### BRIEF DESCRIPTION OF THE DRAWINGS

FIG. 1 illustrates an enclosure for housing PCBs, according to the prior art;

FIG. 2 illustrates an isometric view of the PCB chassis, according to some embodiments;

FIG. 3A illustrate a PCB chassis viewed directly down the z-axis, according to some embodiments;

FIG. 3B illustrate a PCB chassis viewed directly down the x-axis, according to some embodiments; and

FIG. 4 is a flowchart diagram illustrating a method for constructing an enclosure, according to some embodiments.

While the invention is susceptible to various modifications and alternative forms, specific embodiments thereof are shown by way of example in the drawings and are herein described in detail. It should be understood, however, that the drawings and detailed description thereto are not intended to limit the disclosure to the particular form disclosed, but on the contrary, the intention is to cover all modifications, equivalents and alternatives falling within the spirit and scope of the present disclosure, including the appended claims. Particular features, structures, or characteristics may be combined in any suitable manner consistent with this disclosure.

It is to be understood that the terminology used herein is for the purpose of describing particular embodiments only, and is not intended to be limiting. As used herein, the singular forms “a”, “an”, and “the” include singular and plural referents unless the content clearly dictates otherwise. Furthermore, the words “can” and “may” are used throughout this application in a permissive sense (i.e., having the potential to, being able to), not in a mandatory sense (i.e., must). The term “include,” and derivations thereof, mean “including, but not limited to.” The term “coupled” means directly or indirectly connected.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “mobile device configured to generate a hash value” is intended to cover, for example, a mobile device that performs this function during operation, even if the device in question is not currently being used (e.g., when its battery is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed mobile computing device, for example, would not be considered to be “configured to” perform some specific function, although it may be “configurable to” perform that function. After appropriate programming, the mobile computing device may then be configured to perform that function.

Reciting in the appended claims that a structure is “configured to” perform one or more tasks is expressly intended not to invoke 35 U.S.C. §112(f) for that claim element. Accordingly, none of the claims in this application as filed are intended to be interpreted as having means-plus-function elements. Should Applicant wish to invoke Section 112(f) during prosecution, it will recite claim elements using the “means for” [performing a function] construct.

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

### DETAILED DESCRIPTION

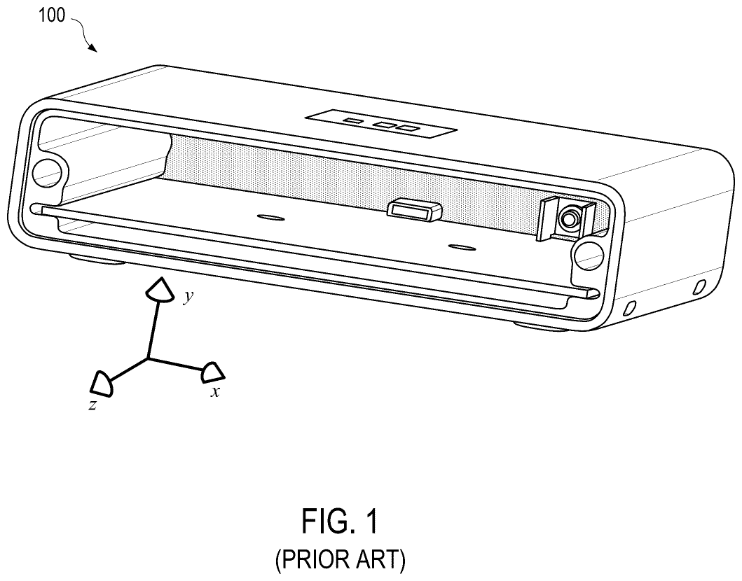

### FIG. 1—Enclosure for PCBs

FIG. 1 illustrates an enclosure 100 for housing PCBs, according to the prior art. The illustrated enclosure consists of a hollow extrusion with slots on either side. The slots are arranged such that a PCB may be slid into and affixed within the enclosure. These enclosures are cost-effective, but may have issues with mounting and heat dissipation. For example, the PCB is held in the slots on the sides of the extrusion, but this is usually a loose fit which may be unsuitable for grounding or mechanical stability. The PCB may be mounted to an end cap, but then that end cap has to be mounted back to the enclosure, which may lead to accumulated tolerance error. In addition, because the PCB has to be slid into the enclosure, it may be difficult to achieve good thermal contact between hot components and the exterior. For example, direct thermal contact only occurs on the left and right edges of the PCB that are in contact with the slots. This poor thermal contact may degrade performance for the PCB.

Some implementations utilize a gap pad to provide thermal dissipation, but sliding a gap pad into the enclosure may shear between the enclosure and the PCB as it is installed, which may damage the PCB. This makes it difficult to locate & causes it to peel up. We can protect the gap pad with some sort of cover, but now that cover is in the heat conduction path and needs to be secured inside the device somehow. Electromagnetic interference (EMI) edge gasketing on the edges of the board can help with grounding, but does very little to mechanically retain the board or sink heat. Designing an enclosure with tight gaps and precise tolerances for components may help, but doesn't solve the problem because the extrusion process may have comparatively loose tolerances, and post-machining a deep channel is highly impractical and expensive.

Wedge lock card retainers address some of these issues, but they come with several drawbacks. For example, wedge locks only work in compression. Accordingly, they're difficult to deploy in the center of a board, and are better suited to grabbing PCB edges.

To thermally sink components, a wedge lock utilizes a continuous thermally conductive path between the edge of the board and the hot component. This is inefficient and unrealistic for many designs, especially when you've got a single hot component on a board that should be kept cool, or you have electrical isolation between the board edge and the hot component. Embodiments herein address these and other concerns by designing a PCB chassis that integrates a wedge locking mechanism with the enclosure using sliding dovetail rails, as described in greater detail below.

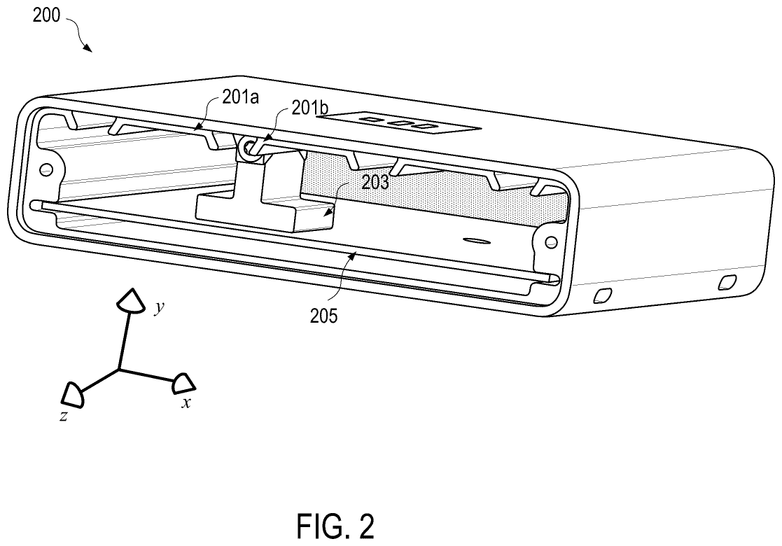

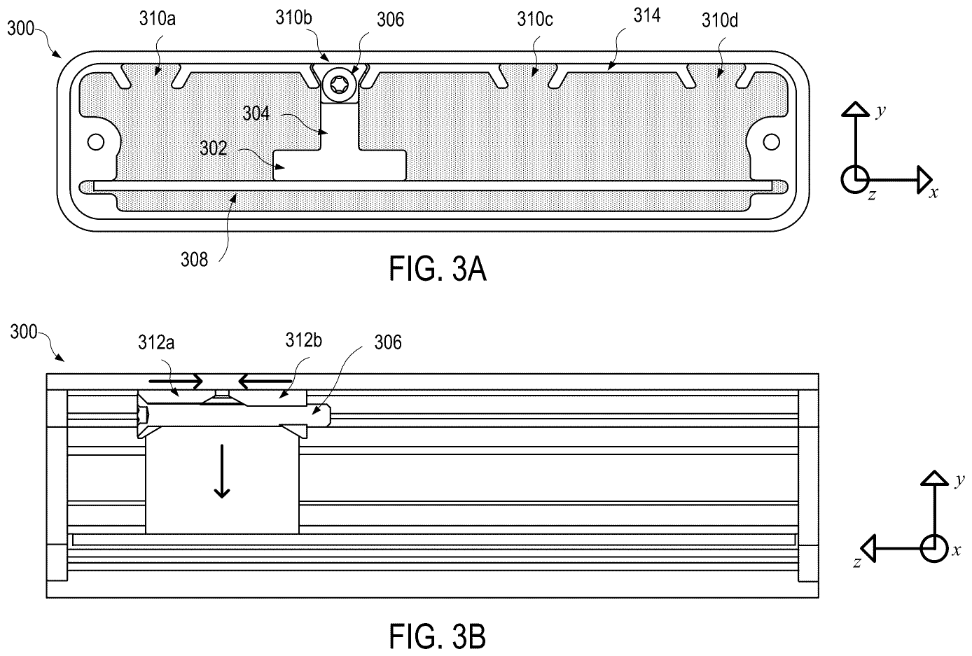

### FIGS. 2 and 3A-B—Dovetail Rail PCB Chassis

FIGS. 2 and 3A-B illustrate a PCB chassis including an enclosure with custom dovetail rails, according to some embodiments. FIG. 2 illustrates an isometric view of the PCB chassis 200, while FIGS. 3A and 3B illustrate a PCB chassis 300 viewed directly down the z-axis and the x-axis, respectively. The PCB chassis may be configured to house any of a variety of types of PCBs, including but not limited to processor chips, field programmable gate arrays (FPGAs), programmable logic devices (PLDs), application specific integrated circuits (ASICs), or other devices, in various embodiments. In some embodiments, the PCB chassis may be a mioDAQ device.

The illustrated enclosure provides several advantages over existing designs. For example, a heat spreader or electrical contact 203 may be slid into the enclosure together with the PCB 205 (i.e., after it is affixed to the PCB), without a risk of shearing or rolling. The heat spreader(s) may lock directly into the enclosure instead of only attaching to the PCB (and potentially compressing it). This allows the board to directly mount to the heat spreader, or a gap pad may be placed close to the hot components, without damaging the components during installation.

Depending on the construction, the heat spreader may be electrically insulative or conductive, allowing it to shield or isolate components, as desired. The heat spreader doesn't require a tight fit; components may operate effectively with typical extruded tolerances (e.g., +/−0.02 inches for a standard tolerance, or +/−0.013 inches for higher precision tolerance. Other tolerances may also be used). If additional precision is required, the heat spreader components are small and easy to machine. The heat spreader applies thermal contact to the PCB, rather than requiring the heat to spread across the board before making it into a point of contact on the side of the enclosure.

In some embodiments, the heat spreader includes a pedestal that is composed of a thinner upper portion 304 and a wider base portion 302, as illustrated in FIG. 3A. The pedestal may be composed of any desired heat-conductive material, such as solid copper or aluminum, or another thermally conductive material. The wider base portion provides greater surface area for heat dissipation, and the area of the base may be determined based on the size of the hot component(s) of the PCB that are to be cooled. The width of the upper portion (along the x-direction) may be selected so that it fits into the dovetail rail, whereas the depth of the upper portion may correspond to that of the base portion. Other shapes may be also used, as desired, to improve heat conductance, accommodate the shape or structure of the PCB and/or the enclosure, or for other reasons.

The enclosure includes one or more sliding dovetail rails arranged along the extrusion direction (the “z” direction in FIGS. 2 and 3A-B). The dovetail rail is configured to capture the wedge mechanism of the heat spreader. The dovetail rail may be composed of two rails (e.g., 201a and 201b) that are attached to the ceiling of the enclosure in their middle, and flare out on the edges so that two adjacent rails from a dovetail shape configured to receive the two wedges of the heat spreader. The enclosure may be configured to house the PCB while it is arranged along a first plane (the x-z plane in FIG. 2).

In some embodiments, the dovetail rails are configured to affix one or more heat spreaders to the enclosure at a customizable position along a first direction (the z-direction) while the one or more heat spreaders are in thermal contact with the PCB. For example, the heat spreader(s) may be affixed to the PCB prior to insertion in the enclosure, and the heat spreader(s) and the PCB may be slid together as a unit into the enclosure, with the PCB sliding along the rails on either side of the enclosure, while the heat spread slides along the dovetail rail. When the PCB is positioned at the desired depth inside the enclosure (e.g., when it is fully inserted, and potentially when it clicks or locks into place), the heat spreader(s) may be affixed to the dovetail rail(s), where they then provide thermal contact to both the PCB (at the bottom surface) and the roof of the enclosure (at the top surface). The heat spreader may then facilitate heat dissipation for the contacted area of the PCB, by providing a shorter path to the exterior of the enclosure.

In some embodiments, the dovetail rail(s) are configured to affix the heath spreader(s) via a wedge locking mechanism. For example, the heat spreader may include two wedges 312a and 312b, as shown in FIG. 3B. The front wedge 312a has a countersunk clearance hole that a screw 306 runs through. As the screw tightens the mechanism, the front wedge gets pulled tight against the pedestal of the dovetail rail and the ceiling of the enclosure. The rear wedge 312b has a threaded hole that engages with the screw. As the screw tightens further, the rear wedge also gets pulled tight against the pedestal of the dovetail rail and the ceiling of the enclosure. The heat spreader may further include a pedestal with a clearance slot that the screw runs through. As the screw tightens, the wedges pull tight against it and pushes it down into the sliding dovetail, centering the pedestal and locking it into position via friction. The bottom of the pedestal can be modified freely, e.g., with screw holes for hard mounting, or with contact points for a gap pad. The screw is used to tighten and lock the whole structure. Advantageously, the pressure of the tightened screw provides two mechanisms to secure the heat spreader: 1) it raises the wedges to lock them into the dovetail rail and against the ceiling of the enclosure, and 2) it presses down on the pedestal to secure it against the PCB. Using a countersunk screw keeps the front wedge centered and reduces the overall length.

The heat spreader provides thermal contact to hot components of the PCB without requiring screw holes or any modifications to the board itself, and without requiring cosmetic changes to the exterior of the extrusion.

In some embodiments, the location(s) of the dovetail rail(s) along the x-direction may be customized to correspond to heat-producing locations on a particular PCB. For example, the enclosure shown in FIG. 3A illustrates four dovetail rails 310a-d, each made from two adjacent flared wings on either side. In some embodiments, a right wing of one dovetail rail and a left wing of a second adjacent dovetail rail are made of a single piece of metal or other rigid material. For example, the flared component 314 forms both the right wing of the rail 310c and the left wing of the rail 310d. The width of the flared component may be predetermined so that the dovetail rails align with the heat producing locations. Note that the right wing of the rightmost rail 310d is part of the side rail that holds the PCB, and similarly for the leftmost rail 310a.

The locations of these dovetail rails may be determined based on the structure of the PCB to be housed, depending on the location(s) of the hot regions of the PCB. In some embodiments, the dovetail rails may be positioned to accommodate a variety of types of PCBs, with potentially differently located hot regions.

The pedestal may be hard mounted to the PCB, which eliminates the need to mount the pedestal elsewhere. This may save board space and allow for a more robust connection than loosely capturing the board at the sides of the enclosure.

While some embodiments are described in terms of a heat spreader that dissipates heat, in some embodiments, in some embodiments the dovetail rail(s) may be configured to affix a magnetic and/or electric absorber or shield, which may be attached to the PCB proximate to sensitive components without modifying the board. Alternatively or additionally, the dovetail rail(s) may be configured to an electrical contact, may be composed of a conductive material and may be used to provide additional electrical contact with specific regions of the PCB, e.g., through which to receive and/or transmit electronic signals. In these embodiments, the pedestal may be composed of a ferrite or metallic material. The location(s) of the dovetail rails in the enclosure may be selected to align with an area of the PCB that would benefit from electromagnetic shielding and/or additional electrical contacts, for example.

In some embodiments, front and rear endcaps may be mounted using the dovetail rails similar to how the heat spreader is mounted. This may eliminate screw chases, saves space on the edges of the device, and reduces gaps for emissions.

In some embodiments, the heat spreader may be configured to mount to multiple dovetail slots for increased stability, and a standard dovetail spacing may allow the same heat spreader to be used with different enclosures.

Using standard dovetail sizing and angles would allow the wedges to be reused across multiple products; conversely, different angles & dimensions might be useful for miniaturization, stability, precision, etc.

In some embodiments, a spring mechanism may be used in place of the screw for blind installations where a screw can't be tightened. A spring/compliant mechanism may be built into the pedestal to compensate for wide tolerances and provide consistent compression. The spring mechanism may utilize a roll pin, in some embodiments.

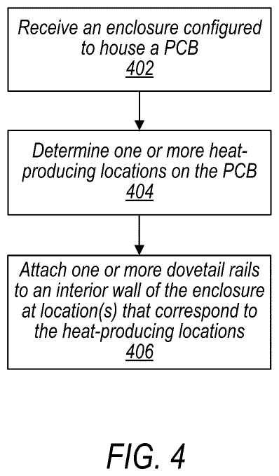

### FIG. 4—Method for Designing an Electronics Chassis

FIG. 4 is a flowchart diagram illustrating a method for designing an electronics chassis configured to house a printed circuit board (PCB), according to some embodiments. The described methods may attach dovetail rails at customized locations within an enclosure, which may be used to provide targeted heat dissipation via heat spreaders to specific heat-producing locations on the PCB.

At 402, an enclosure is received that is configured to house a printed circuit board (PCB). The enclosure may have rails along its interior wall that are structured to receive the PCB as it is slide into the enclosure, and it may include a mechanism (e.g., a latch) to lock the PCB in place when fully inserted.

At 404, one or more heat-producing locations on the PCB are determined. For example, the heat-producing locations may correspond to the locations of processors or other computationally active components of the PCB.

At 406, one or more dovetail rails are attached to an interior wall of the enclosure at one or more locations. The one or more locations may be selected to correspond to the one or more heat-producing locations on the PCB. The dovetail rails may be attached such that the length of the rail runs along the z-direction (according to the axes defined in FIGS. 2 and 3A-B), and the location along the x-direction is selected to correspond to the location(s) of the heat-producing locations along the x-direction. The dovetail rails may be attached to the interior wall via a variety of mechanisms, including but not limited to welding, soldering, adhesives, or a mechanical attachment mechanism.

In some embodiments, the method further includes affixing one or more heat spreaders to the PCB, and inserting the one or more heat spreaders and the PCB into the enclosure. The one or more heat spreaders slide along the one or more dovetail rails while being inserted into the enclosure. The method may further include activating a wedge locking mechanism to affix the one or more heat spreaders to the one or more dovetail rails at a first depth (in the z-direction).

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as embodiments. Elements and materials may be substituted for those illustrated and described herein, steps in processes and procedures may admit permutation of order, and certain features of the invention may be utilized independently, all as would be apparent to one skilled in the art after having the benefit of this description of the invention. Changes may be made in the elements described herein without departing from the spirit and scope of the invention as defined in the following claims.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A chassis, comprising:
an enclosure configured to house a printed circuit board (PCB) while arranged along a first plane, wherein the enclosure comprises one or more dovetail rails arranged along a first direction that is parallel to the first plane;
wherein the one or more dovetail rails are configured to affix one or more heat spreaders to the enclosure at a customizable position along the first direction while the one or more heat spreaders are in thermal contact with the PCB.

2. The chassis of claim 1,
wherein the one or more dovetail rails are configured to affix the one or more heat spreaders via a wedge locking mechanism.

3. The chassis of claim 2,
wherein the wedge locking mechanism utilizes one or more screws or springs that expand wedge portions of the one or more heat spreaders into the one or more dovetail rails and press a pedestal of the one or more heat spreaders into the PCB.

4. The chassis of claim 1,
wherein the one or more dovetail rails are configured to provide thermal contact between the affixed one or more heat spreaders and a ceiling of the enclosure.

5. The chassis of claim 1, further comprising:
the one or more heat spreaders, wherein the one or more heat spreaders are arranged to slide along the one or more dovetail rails while affixed to the PCB and while the PCB is slid into the enclosure.

6. The chassis of claim 1,
wherein one or more locations of the one or more dovetail rails along a second direction are selected to correspond to one or more heat-producing locations on the PCB, wherein the second direction is perpendicular to the first direction and parallel to the first plane.

7. The chassis of claim 1,
wherein a first heat spreader of the one or more heat spreaders comprises a pedestal, wherein the pedestal comprises a base portion and an upper portion, wherein the base portion is wider than the upper portion along a second direction, wherein the second direction is perpendicular to the first direction and parallel to the first plane, wherein the base portion is configured to have thermal contact with the PCB while the one or more heat spreaders are affixed to the enclosure, and wherein the upper portion is configured to transfer heat between the base portion and a ceiling of the enclosure.

8. The chassis of claim 1,
wherein the one or more dovetail rails comprise a first dovetail rail and a second dovetail rail,
wherein a right wing of the first dovetail rail and a left wing of the second dovetail rail are part of a single piece of metal.

9. A chassis, comprising:
an enclosure configured to house a printed circuit board (PCB) while arranged along a first plane, wherein the enclosure comprises one or more dovetail rails arranged along a first direction that is parallel to the first plane;
wherein the one or more dovetail rails are configured to affix one or both of an electrical contact and an electromagnetic shields to the enclosure at a customizable position along the first direction while the electrical contact and/or the electromagnetic shields are in contact with the PCB.

10. The chassis of claim 9,
wherein the one or more dovetail rails are configured to affix one or both of the electrical contact and the electromagnetic shield via a wedge locking mechanism.

11. The chassis of claim 10,
wherein the wedge locking mechanism utilizes one or more screws or springs that expand wedge portions of one or both of the electrical contact and the electromagnetic shield into the one or more dovetail rails and press a pedestal of one or both of the electrical contact and the electromagnetic shield into the PCB.

12. The chassis of claim 9,
wherein the one or more dovetail rails are configured to provide contact between one or both of the affixed electrical contact and electromagnetic shield and a ceiling of the enclosure.

13. The chassis of claim 9, further comprising:
one or both of the electrical contact and the electromagnetic shield, wherein one or both of the electrical contact and the electromagnetic shield are arranged to slide along the one or more dovetail rails while affixed to the PCB and while the PCB is slid into the enclosure.

14. The chassis of claim 9,
wherein one or more locations of the one or more dovetail rails along a second direction are selected based on one or more locations on the PCB, wherein the second direction is perpendicular to the first direction and parallel to the first plane.

15. A method, comprising:
receiving an enclosure configured to house a printed circuit board (PCB);
determining one or more heat-producing locations on the PCB;
attaching one or more dovetail rails to an interior wall of the enclosure at one or more locations, wherein the one or more locations are selected to align with the one or more heat-producing locations on the PCB.

16. The method of claim 15, further comprising:
affixing one or more heat spreaders to the PCB;
inserting the one or more heat spreaders and the PCB into the enclosure, wherein the one or more heat spreaders slide along the one or more dovetail rails while being inserted into the enclosure; and
activating a wedge locking mechanism to affix the one or more heat spreaders to the one or more dovetail rails at a first depth.

17. The method of claim 16,
wherein the one or more heat spreaders are inserted into the enclosure while affixed to the PCB and while the PCB is slid into the enclosure.

18. The method of claim 16,
wherein the wedge locking mechanism utilizes one or more screws or springs that expand wedge portions of the one or more heat spreaders into the one or more dovetail rails and press a pedestal of the one or more heat spreaders into the PCB.

19. The method of claim 16,
wherein activating the wedge locking mechanism to affix the one or more heat spreaders to the one or more dovetail rails at the first depth provides, by the one or more heat spreaders, thermal contact between the PCB and a ceiling of the enclosure.

20. The method of claim 15,
wherein a first heat spreader of the one or more heat spreaders comprises a pedestal, wherein the pedestal comprises a base portion and an upper portion, wherein the base portion is wider than the upper portion along a second direction, wherein the second direction is perpendicular to the first direction and parallel to the first plane, wherein the base portion is configured to have thermal contact with the PCB while the one or more heat spreaders are affixed to the enclosure, and wherein the upper portion is configured to transfer heat between the base portion and a ceiling of the enclosure.
